(19) United States
(12) Patent Application Publication
(10) Pub. No.: US 2015/0382445 A1
(43) Pub. Date: Dec. 31, 2015

(54) DOUBLE-SIDED FLEXIBLE PRINTED CIRCUIT BOARD INCLUDING PLATING LAYER AND METHOD OF MANUFACTURING THE SAME

(71) Applicant: HICEL CO., LTD., Gyeonggi-do (KR)

(72) Inventor: Eun Kuk Choi, Chungcheongnam-do (KR)

(21) Appl. No.: 14/315,380

(22) Filed: Jun. 26, 2014

(51) Int. Cl. H05K 1/02; C23C 18/31; H05K 3/00; C23C 18/16; H05K 1/11; H05K 1/09

(52) U.S. Cl. CPC H05K 1/028; H05K 1/115; H05K 1/092; H05K 3/0035; C23C 18/1633; C23C 18/31; H05K 2201/032; H05K 2201/05

(57) ABSTRACT

Disclosed is a double-sided flexible printed circuit board, including a flexible substrate including at least one via hole and a via formed therein to connect circuit wirings respectively formed on both sides of the substrate; a patterned wiring layer formed by printing a conductive paste composition in a predetermined circuit wiring pattern on each of both sides of the flexible substrate; an electroless metal plating layer formed on the patterned wiring layer; and a metal plating layer additionally formed on the electroless metal plating layer to increase electrical conductivity of a wiring including the patterned wiring layer and the electroless metal plating layer formed on each of both sides of the flexible substrate, wherein the circuit wirings respectively patterned on both sides of the flexible substrate are electrically connected to each other through the via formed in the via hole. Also provided is a method of manufacturing the same.

### BACKGROUND

1. Field of the Invention

The present invention relates to a double-sided flexible printed circuit board, wherein both sides of a flexible printed circuit board are printed with a conductive paste and then formed with a plating layer, thus increasing electrical conductivity and achieving slimness, and to a method of manufacturing the same.

2. Description of the Related Art

With drastic improvements in the degree of integration within the electronics industry, surface mounting technologies for directly mounting small chips and parts thereof have been developed. Accordingly, electronic parts need to be thinned and miniaturized in order to be easily embedded in more complex and smaller spaces.

In order to cope with such needs, a flexible printed circuit board (FPCB) is being developed. By virtue of the technological advancement of cameras, mobile phone batteries, printers, disk drives, small meters, liquid crystal displays (LCDs), plasma display panels (PDPs) and medical instruments, the use of a double-sided flexible printed circuit board, which allows for easy lamination and is highly available, can be drastically increased, and thus further development and demand for the techniques thereof are increasing.

Generally, printed circuit boards are classified into three types: rigid printed circuit boards, flexible printed circuit boards, and rigid-flexible printed circuit boards, which are a combination of the previous two types, and depend on the physical properties of the materials thereof A rigid printed circuit board includes a fixed printed circuit board as commonly appreciated, and a flexible printed circuit board is utilized when a printed circuit board that is flexible needs to be mounted in a bent or folded state within an electronic device.

Moreover, the double-sided flexible printed circuit board, which allows easy lamination and is highly available, is typically manufactured in the same manner as a rigid printed circuit board. Specifically, a copper clad laminate including a polyimide substrate and copper foils formed on both sides thereof is cut to a predetermined size, multilayered, and processed to have through holes by mechanical drilling using an numerical control (NC) drill. Then, the through holes are imparted with conductivity using electroless plating and electroplating based on a conventional robotic process, so that the upper and lower sides of the circuit board are electrically connected to each other, followed by dry film lamination, exposure, development and etching, thereby forming a circuit pattern.

In regard thereto, Korean Patent Application Publication No. 10-2004-0005404 discloses a method of manufacturing a double-sided flexible printed circuit board, by continuously forming a plurality of through holes in a copper clad laminate by a roll-to-roll process using a UV laser drill, plating the through holes with a metal to impart conductivity to the through holes using a roll-to-roll process so that the upper and the lower copper foil are connected, adhering a dry film to the upper and the lower side of the copper clad laminate using a roll-to-roll process, and subjecting the copper clad laminate to exposure, development and etching using a roll-to-roll process, thereby forming a desired circuit pattern.

However, the manufacturing process including etching using the copper clad laminate is problematic because of a complicated working process, increased working time and cost, and eco-unfriendliness.

A conductive ink/paste may be used as a material for generating a circuit pattern, instead copper foil, and allows for the relatively inexpensive manufacturing of printed circuit boards (PCBs).

The conductive ink results from dispersing metal particles having a diameter of one to tens of nanometers in a solvent. When the conductive ink is printed on a substrate and heated to a predetermined temperature, an organic additive such as a dispersant may be volatilized, and the spaces between the metal particles may be shrunken and sintered, thus forming an electrically and mechanically interconnected conductor. Alternatively, the conductive paste may be obtained by dispersing metal particles having a diameter of hundreds to thousands of nanometers in an adhesive resin. When the conductive paste is printed on a substrate and heated to a predetermined temperature, the resin may be cured and electrical and mechanical contacts between the metal particles may be fixed, thus forming an interconnected conductor.

However, in the printed circuit board using the conductive paste as above, existing pastes include a binder component to enhance adhesion to the substrate, and such a component may decrease conductivity, resulting in increased resistance.

Furthermore, when the conductive material has a particle size at the micro-level (3˜10 μm), the paste may include larger amounts of binder between the particles, undesirably causing the resistance to further increase.

To resolve these problems, methods have been proposed to increase the conductivity by forming a metal layer 20˜30 μm thick through electroplating on a wiring layer made of the conductive paste.

As conventional techniques for forming the metal layer through electroplating on the wiring layer made of the conductive paste, Korean Patent Application Publication No. 10-2010-0064494 discloses a direct printing method, including printing a pattern on a substrate with a paste composition including conductive particles, and then electroplating the substrate. Also, Korean Patent Application Publication No. 10-2010-0013033 discloses a method of manufacturing a printed circuit board, including printing a conductive paste on a substrate to form a wiring layer, and performing electroplating with a metal having high melting temperature on the wiring layer to form a primary plating layer.

However, methods of forming the metal layer through electroplating on the conductive paste to increase electric conductivity of the wiring layer, including the conductive paste layer, is disadvantageous because the plating process may not be efficiently implemented and is attributable to the high resistance of the conductive paste during the course of electroplating, or the plating thickness may significantly vary due to variations in resistance.

These problems may more readily occur when forming a wiring that has a length much greater than the width thereof on the substrate, ultimately deteriorating the thickness uniformity of the plating layer.

With reference to FIGS. 1A and 1B, FIG. 1A illustrates a conventional printed circuit board having a wiring formed by printing a pattern with a conductive paste (i.e., a silver (Ag) paste) on a flexible substrate and then forming an electroplating layer thereon, with a circuit width of 1 mm and a length of 750 mm. As such, resistance applied to both terminals of the wiring having the printed Ag paste is as large as about 160 ohms (Ω), which may deteriorate the uniformity of the wiring upon subsequent electroplating.

The start point of the wiring is positioned close to the electrode upon electroplating on the conductive paste, and the reduction reaction of metal is efficiently carried out, thus facilitating the formation of the plating layer on the conductive paste layer. However, as the wiring layer including the paste layer is located farther away from the start point, the electrical conductivity of the paste becomes lower than that of metal. Furthermore, the efficiency of the reduction reaction of the metal ion may decrease due to the presence of resistance depending on the length of the conductive paste. Hence, as the wiring becomes further from the start point of the electrode, the resulting plating layer may become thinner, and the wiring may be discontinuously plated.

As seen in the printed circuit board of FIG. 1A, when the paste layer having four wires formed within the dotted oval of the wiring layer of FIG. 1A is electroplated, then, as shown in FIG. 1B, the thickness of the electroplating layer at the right closest to the electrode is 34 μm, the second wiring from the right is 25 μm thick, the third wiring is 16 μm thick and the left plating is 13 μm thick. Therefore, depending on the length of the wiring, the thickness of the electroplating layer may become non-uniform.

Hence, if the thickness of the plating layer increases, a final circuit board may become thick, and printing defects may be caused due to the high thickness.

When the plating amount is increased upon electroplating to increase the thickness of the plating layer, not only the upper end of the wiring layer, but also the lateral portion thereof may be plated, making it impossible to narrow the line width (e.g., pitch width) of the wiring.

In order to overcome these problems, a pattern may be formed using an expensive nano-level paste (e.g., particle size 50 nm) having lower resistance than typical Ag pastes (e.g., particle size 3˜5 μm), but a cost burden due to the use of these raw materials may increase and thus there is no advantage in terms of price compared to existing products. Even when a nano-level paste is used, increasing electrical conductivity of the wiring formed of the conductive paste on a printed circuit board is still required.

Also, there is a continuous need for research and development into a novel double-sided flexible printed circuit board wherein the electrical conductivity of the wiring formed of the conductive paste is high and the circuit wiring layer is thinner.

### SUMMARY

Accordingly, one embodiment of the present invention provides a double-sided flexible printed circuit board, wherein circuit wirings formed on the front and the rear side of a flexible substrate are electrically connected to each other by means of at least one via hole, and a wiring having a wiring layer formed of a conductive paste composition on the flexible printed circuit board and a plating layer formed on the wiring layer having high electrical conductivity and thinness.

Another embodiment provides a method of manufacturing a double-sided flexible printed circuit board, wherein in the event of forming a patterned wiring using a conductive paste on the double-sided flexible printed circuit board and forming a metal plating layer thereon, the wiring in the formed plating layer has no discontinuity, and the metal wiring layer has high electrical conductivity in addition to being thin.

In another embodiment of the present invention, provided is a double-sided flexible printed circuit board, having a flexible substrate including at least one via hole and a via formed therein to connect circuit wirings respectively formed on both sides of the substrate; a patterned wiring layer formed by printing a conductive paste composition in a predetermined circuit wiring pattern on each of both sides of the flexible substrate; an electroless metal plating layer formed on the patterned wiring layer; and a metal plating layer additionally formed on the electroless metal plating layer to increase electrical conductivity of a wiring having the patterned wiring layer and the electroless metal plating layer formed on each of both sides of the flexible substrate, wherein the circuit wirings respectively patterned on both sides of the flexible substrate are electrically connected to each other through the via formed in the via hole.

In one embodiment, the substrate may have a thickness of 12 to 100 μm, and may include any one selected from among the following: polybutylene terephthalate, polyethylene terephthalate, polysulfone, polyether, polyetherimide, heat-resistant epoxy, polyarylate, polyimide and FR-4.

In one embodiment, the electroless metal plating layer formed on the patterned wiring layer may have a thickness of 1 to 10 μm, and a metal for the electroless metal plating layer may include any one selected from the following: copper (Cu), tin (Sn), silver (Ag), gold (Au), nickel (Ni), and alloys thereof.

In another embodiment, the metal plating layer which is additionally formed on the electroless metal plating layer may be a metal electroplating layer or an electroless metal plating layer, and a metal for the metal electroplating layer which is additionally formed may include any one selected from the following: nickel (Ni), copper (Cu), tin (Sn), gold (Au), silver (Ag), and alloys thereof or a Ni—P alloy, and a metal for the electroless metal plating layer which is additionally formed may include any one selected from the following: copper (Cu), tin (Sn), silver (Ag), gold (Au), nickel (Ni), and alloys thereof.

In one embodiment, the conductive paste composition may include any one selected from the following: a conductive Ag paste, a conductive Cu paste, a conductive polymer and a gravure paste, or a mixture thereof, and the conductive paste composition may have a particle size of 10 nm to 10 μm.

In another embodiment, the via may be formed in the via hole by filling the via hole with a conductive material, a plating process, or a combination of a plating process and filling the via hole with a conductive material.

In yet another embodiment, filling the via hole with the conductive material may be performed by filling the via hole with a conductive paste or a conductive ink including metal nanoparticles using inkjet printing.

In yet still another embodiment, the double-sided flexible printed circuit board may further include a seed metal layer formed of any one selected from the following: Au, Ag, platinum (Pt), Cu, Ni, iron (Fe), palladium (Pd), cobalt (Co), and alloys thereof on the patterned wiring layer to form the electroless metal plating layer.

In one embodiment, provided is a method of manufacturing a double-sided flexible printed circuit board, including printing a conductive paste composition having any one selected from the following: a conductive Ag paste, a conductive Cu paste, a conductive polymer and a gravure paste or a mixture thereof in a predetermined pattern on one side of a flexible printed circuit board, thus forming a patterned wiring layer which covers a portion for forming a via hole; forming a blind via hole as the via hole at a predetermined portion of the other side of the flexible printed circuit board including the patterned wiring layer, except for the patterned wiring layer which covers the via hole of one side of the flexible printed circuit board; forming a via in the via hole to impart conductivity to the via hole; printing a conductive paste composition having any one selected from the following: a conductive Ag paste, a conductive Cu paste, a conductive polymer and a gravure paste or a mixture thereof in a predetermined pattern on the other side of the flexible printed circuit board, thus forming a patterned wiring layer, so that the wiring layer formed on the other side of the flexible printed circuit board is connected to the via formed in the via hole and thus electrically connected to the wiring layer formed on one side of the flexible printed circuit board; subjecting a transition metal to electroless plating on the patterned wiring layer provided on each of both sides of the flexible printed circuit board, thus forming an electroless plating layer; and additionally forming a metal electroplating layer or an electroless metal plating layer on the electroless plating layer formed on each of both sides of the flexible printed circuit board in order to increase the electrical conductivity of a wiring having the patterned wiring layer and the electroless metal plating layer.

In another embodiment, provided is a method of manufacturing a double-sided flexible printed circuit board, including printing a conductive paste composition having any one selected from the following: a conductive Ag paste, a conductive Cu paste, a conductive polymer and a gravure paste or a mixture thereof in a predetermined pattern on one side of a flexible printed circuit board, thus forming a patterned wiring layer which covers a portion for forming a via hole; printing a conductive paste composition having any one selected from the following: a conductive Ag paste, a conductive Cu paste, a conductive polymer and a gravure paste or a mixture thereof in a predetermined pattern on the other side of the flexible printed circuit board, thus forming a patterned wiring layer; forming a blind via hole as the via hole at a predetermined portion of the other side of the flexible printed circuit board including the patterned wiring layer, except for the patterned wiring layer which covers the via hole of one side of the flexible printed circuit board; forming a via in the via hole to impart conductivity to the via hole so that the wiring layers respectively formed on both sides of the flexible printed circuit board are electrically connected to each other; subjecting a transition metal to electroless plating on the patterned wiring layer and the via on each of both sides of the flexible printed circuit board, thus forming an electroless plating layer; and additionally forming a metal electroplating layer or an electroless metal plating layer on the electroless plating layer provided on each of both sides of the flexible printed circuit board in order to increase the electrical conductivity of a wiring having the patterned wiring layer and the electroless metal plating layer.

In one embodiment, at least one step of the method may be performed using a roll-to-roll process.

In another embodiment, forming the via hole may be performed by etching using laser drilling.

In yet another embodiment, forming the via in the via hole to impart conductivity to the via hole may be performed by filling the via hole with a conductive material, a plating process, or a combination of a plating process and filling the via hole with a conductive material.

In still yet another embodiment, the method may further include forming a seed metal layer using any one selected from the following: Au, Ag, Pt, Cu, Ni, Fe, Pd, Co, and alloys thereof on the patterned wiring layer to form the electroless metal plating layer, between forming the patterned wiring layer using the conductive paste and forming the electroless plating layer using a transition metal on the patterned wiring layer.

In one embodiment, the method may further include removing smear from a wall and a bottom of the via hole, after forming the via hole.

Accordingly, a double-sided flexible printed circuit board can be more easily manufactured in an eco-friendly fashion, compared to conventional circuit boards made using an etching process. Furthermore, compared to conventional techniques for forming an electroplating layer on a conductive paste layer, a metal plating layer can be more uniformly formed on a conductive paste layer on the flexible printed circuit board, and the electrical conductivity of the wiring can be increased, as described herein.

Furthermore, as described herein, the circuit can be formed so that the line width of the wiring is narrow while the plating thicknesses including the paste thickness, the electroless plating thickness, and the electroplating thickness are set at about 3˜5 μm, and thus the wiring layer becomes thin, compared to conventional techniques of forming the metal layer through electroplating on the conductive paste layer on the front and the rear side of the double-sided flexible printed circuit board.

### BRIEF DESCRIPTION OF THE DRAWINGS

The above and other embodiments of the present invention will be more clearly understood from the following detailed description taken in conjunction with the accompanying drawings, in which:

FIG. 1A is a top plan view illustrating a conventional circuit board including a pattern printed with a conductive paste (e.g., Ag paste) on a flexible substrate and an electroplating layer formed thereon;

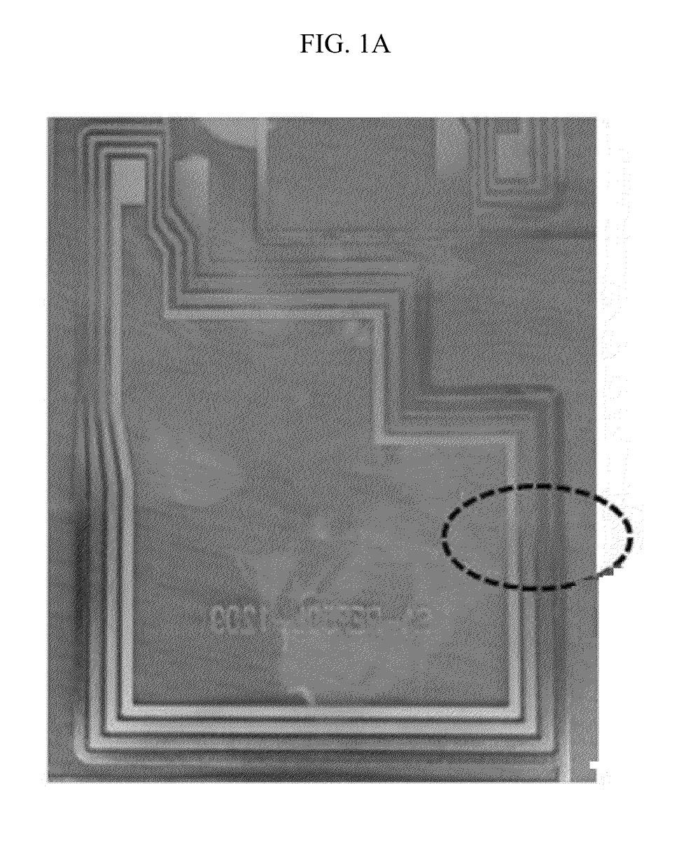

FIG. 1B illustrates the thickness of the electroplating layer of the conventional circuit board in which the pattern is printed with the conductive paste (e.g., Ag paste) on the flexible substrate and the electroplating layer is formed thereon;

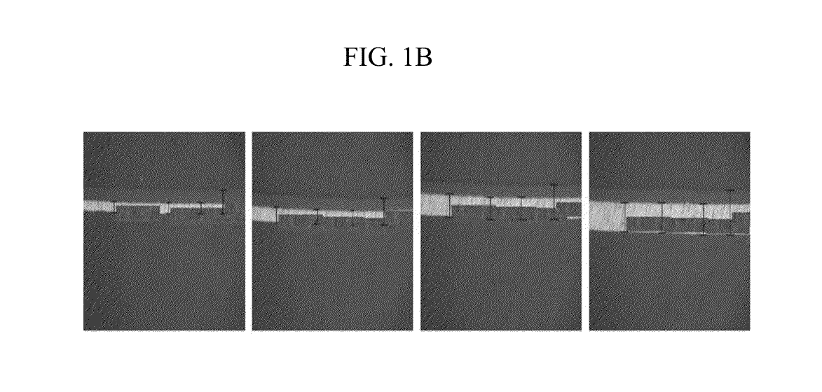

FIG. 2 is a cross-sectional view illustrating a double-sided flexible printed circuit board according to one embodiment of the present invention;

FIG. 3 is a cross-sectional view illustrating a double-sided flexible printed circuit board according to another embodiment of the present invention;

FIG. 4 shows cross-sectional views illustrating a process of manufacturing the double-sided flexible printed circuit board according to one embodiment of the present invention;

FIG. 5 shows cross-sectional views illustrating a process of manufacturing the double-sided flexible printed circuit board according to another embodiment of the present invention; and

FIG. 6 is a graph illustrating changes in resistance after formation of an electroless Cu plating layer and after formation of a Cu electroplating layer on the electroless Cu plating layer, on the conductive paste layer of the printed circuit board according to one embodiment of the present invention.

### DETAILED DESCRIPTION

Hereinafter, a detailed description will be given of a double-sided flexible printed circuit board and a method of manufacturing the same with reference to the appended drawings. The embodiments described herein may be modified or may encompass a variety of forms, and therefore, the following description does not limit the present invention to specific embodiments described herein, and should be understood to include all variations, equivalents, or substitutions within the spirit and scope of the present invention. For the sake of clarity, the dimensions of the structures in the drawings are exaggerated. In the description, the terms “first” and/or “second” may be used to distinguish any one element from another element.

Unless otherwise defined, all of the terms used herein, including technical or scientific terms, have the same meanings as those typically understood by persons having ordinary skill in the art to which the present invention belongs. Terms such as those defined in general dictionaries should be construed to match to the meanings in the contexts of the related art, and should not be interpreted ideally or exaggeratedly as the formal meanings, unless obviously defined herein.

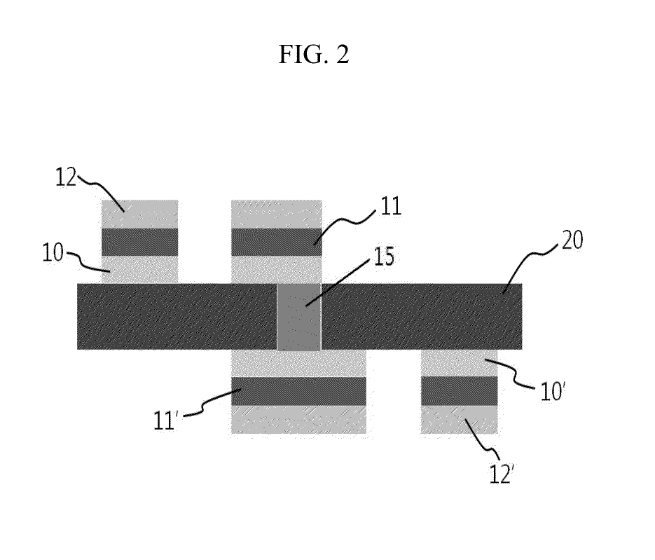

FIG. 2 is a cross-sectional view illustrating a double-sided flexible printed circuit board according to one embodiment of the present invention.

As illustrated in FIG. 2, the printed circuit board according to the present invention includes a flexible substrate 20 including at least one via hole and a via formed therein to connect circuit wirings formed on the front and the rear side of the substrate to each other; patterned wiring layers 10, 10′ respectively formed by printing a conductive paste composition in a predetermined circuit wiring pattern on the front and the rear side of the flexible substrate; electroless metal plating layers 11, 11′ respectively formed on the patterned wiring layers; and metal plating layer 12, 12′ additionally formed on the electroless metal plating layers to increase electrical conductivity of the wirings including the patterned wiring layers and the electroless metal plating layers on the front and the rear side of the flexible substrate. As such, the circuit wirings 10 to 12, 10′ to 12′ respectively patterned on the front and the rear side of the flexible substrate are electrically connected to each other by means of the via 15 formed in the via hole.

In the present invention, the flexible substrate has flexibility, and may be formed by a printing process using a conductive paste composition. Any flexible substrate may be used without limitation so long as it has insulating properties. The flexible substrate may include any one selected from the following: polybutylene terephthalate, polyethylene terephthalate, polysulfone, polyether, polyetherimide, heat-resistant epoxy, polyarylate, polyimide, and FR-4.

The thickness of the flexible substrate is without limitation so long as it is able to ensure flexibility, and may be set to 8 to 1000 μm, or 12 to 100 μm.

The flexible substrate includes at least one via 15 and via hole 15′ to connect circuit wirings respectively formed on the front and the rear side thereof.

The via hole designates a perforation processed to acquire electrical connection between the layers in a printed circuit board, and typically means that both sides thereof are opened. On the other hand, a blind via hole refers to a via hole, either side of which is closed in a printed circuit board. A via land refers to a conductor at one end of the pattern of the printed circuit board connected to the via hole to achieve part mounting or connection.

The via hole may be formed by mechanical drilling or laser drilling. As such, the wiring layer made of the conductive paste is able to form a via land, as necessary. The via land is formed on a portion for forming a via hole, and may have a certain shape in which the inside of the wiring is filled with a conductive paste composition or a donut shape in which the inner center of the wiring is unoccupied, when viewed from a two-dimensional plane. The via land may be connected to the via hole.

In an exemplary embodiment, the via hole may be formed by etching using an ultraviolet (UV) or carbon dioxide (CO₂) laser. As such, a laser beam the size of which is greater than the diameter of the via hole and smaller than the size of the via land. The via hole has a diameter of 20 to 200 μm, and is formed at an angle of 5° or less, wherein a difference between the upper and the lower diameter of the via hole may fall in the range within 10%.

As the via is formed in the via hole, the via hole may be imparted with conductivity. The via 15, which is a medium for interlayer wiring connection, may be formed by filling the via hole 15′ with a conductive material.

In one embodiment, the via is formed by filling the via hole with a conductive ink or a conductive paste having Ag powder and a thermosetting resin or a UV curable resin for binding the Ag powder, and then applying heat or UV to cure it. The thermosetting resin or the UV curable resin is a resin which is maintained as a liquid at room temperature and then cured when heat or UV is applied, and may include epoxy resin, polyester resin, acrylic resin, xylene resin, polyurethane resin, urea resin, amino resin, and alkyd resin.

Alternatively, the via 15 may be formed by a plating process. This process imparts conductivity to the via hole in such a manner that a flexible circuit board including the via hole 15′ undergoes electroplating or electroless plating Imparting conductivity using the plating process may be executed by means of a bottom-up filling process.

Alternatively, the via may be formed by a combination of a plating process and a process of filling the via hole with a conductive material. Specifically, the via hole may be imparted with conductivity by forming a metal plating film on the surface of the via hole using a plating process and then filling the remaining empty space with a conductive material.

The conductive paste may contain particles of an electrically conductive material, examples of which include conductive metals, nonmetals, or oxides, carbides, borides, nitrides, and carbonitrides thereof in powder form, and carbonaceous powder such as carbon black and graphite. The conductive paste particles may include, for example, gold (Au), aluminum (Al), copper (Cu), indium (In), antimony (Sb), magnesium (Mg), chromium (Cr), tin (Sn), nickel (Ni), silver (Ag), iron (Fe), titanium (Ti) and alloys thereof, and oxides, carbides, borides, nitrides, and carbonitrides thereof These particles are not particularly limited in shape, and may have a plate shape, a fiber shape, and nano-sized nanoparticles or nanotubes. Such conductive particles may be used alone or in combination.

The conductive paste may further include a binder for enhancing adhesion to the substrate, unlike conductive ink for use in inkjet printing. An organic binder such as epoxy resin, phenol resin (phenol+formaldehyde), polyurethane resin, polyamide resin, acrylic resin, urea/melamine resin, or silicone resin may be used. The amount of the binder may be set to 10 to 80 wt %, or 20 to 70 wt %, based on the total amount of the paste composition, but the present invention is not limited thereto. The binder may cause electrical conductivity of the wiring layer including the conductive paste to decrease, as mentioned above.

In the present invention, the conductive paste composition may have a viscosity of 10,000 to 100,000 cps under conditions of 23° C. and 50 rpm HAKKE RHeoscope measurement standards, but the present invention is not limited thereto.

In addition thereto, an additive such as Ag powder (pigment), natural and synthetic resin (binder), a solvent, a dispersant, a coupling agent or a viscosity controller may be further included.

The conductive paste composition includes any one selected from among a conductive Ag paste, a conductive Cu paste, a conductive polymer and a gravure paste, or a mixture thereof.

The gravure paste is a kind of conductive Ag paste, with a particle size of 2˜3 μm, and may be composed of 75% of Ag powder, 10% of a resin, 13% of a solvent, and 2% of an additive.

The conductive paste composition may have a particle size of 10 nm to 10 μm. A conductive paste having nano-sized particles of 30 to 100 nm or a conductive paste having micro-sized particles of 1 to 7 μm may be used.

Typically, the larger the particle size of the paste, the lower the electrical conductivity of the resulting wiring layer. When the paste particles have a micro-scale size, an effect of increasing conductivity due to the formation of the wiring layer through the electroless plating layer according to the present invention may be further enhanced.

In the present invention, the conductive paste is subjected to direct printing on the substrate, so that a patterned wiring layer may be formed in a pattern desired by a user. Direct printing on a substrate may include screen printing, flexography, rotary printing, gravure printing, offset printing, or dispenser printing. Each printing process may be performed using conventionally known means. Particularly useful is screen printing, gravure printing or offset printing.

The electroless metal plating layer formed on the patterned wiring layer has a thickness of 1 to 10 μm, or 2 to 5 μm.

In the present invention, a metal used for electroless metal plating may include, but is not limited to, any one selected from the following: Cu, Sn, Ag, Au, Ni, and alloys thereof. Preferably useful is Cu, Ag or Ni.

Also, a seed metal layer for forming an electroless metal plating layer may be further disposed between the patterned wiring layer and the electroless metal plating layer.

The seed metal layer functions to improve the reaction rate of electroless plating and the selectivity by adsorbing a seed metal onto the paste layer so as to reduce a metal ion for forming an electroless chemical plating layer.

The metal for the seed metal layer may be selected from the following: Au, Ag, Pt, Cu, Ni, Fe, Pd, Co, and alloys thereof, and any component may be used so long as it is a transition metal salt of a seed metal component, such as a halide, a sulfate, an acetate, or a complex of a seed metal component.

Also, the seed metal layer may further contain a transition metal component, in addition to the seed metal component.

The transition metal component, in addition to the seed metal, may contain a transition metal salt, such as a metal halide, a metal sulfate, or a metal acetate. To this end, a salt having the same metal component as that of the electroless plating layer formed on the conductive paste layer may be used.

When the seed metal layer is used in this way, it enables the electroless plating layer to be more rapidly formed and also plays a role in forming the electroless plating layer only on the wiring layer made of the conductive paste.

As illustrated in FIG. 2, the metal plating layers 12, 12′ may be additionally formed on the electroless metal plating layers. These metal plating layers each may be composed of a metal electroplating layer or an electroless metal plating layer. Specifically, the electroless metal plating layer which is additionally formed may include any one selected from the following: Cu, Sn, Ag, Au, Ni, and alloys thereof, and may be formed under the same conditions as in the electroless metal plating layers 11, 11′ as above.

On the other hand, the metal electroplating layer which is additionally formed may include any one selected from the following: Ni, Cu, Sn, Au, Ag, and alloys thereof, or a Ni—P alloy, and is provided on the electroless plating layers 11, 11′. Hence, as electroplating is carried out on the wiring layer having higher electrical conductivity than that of the conductive paste, the conductivity of the wiring layer may be further enhanced.

Also, metal plating layers (not shown) may be further formed on the metal plating layers 12, 12′ which are additionally provided on the electroless metal plating layers 11, 11′, depending on the needs of users.

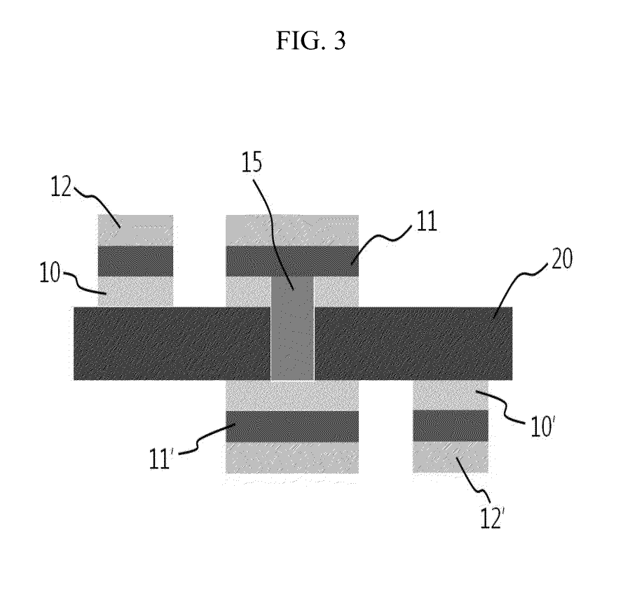

As for the double-sided flexible printed circuit board according to the present invention, when the via land is formed by the conductive paste, the height of the via which is formed by a filling process or a plating process may be set up to the height of the conductive paste layer, which may be more easily understood as illustrated in FIG. 3. FIG. 3 illustrates a double-sided flexible printed circuit board according to another embodiment of the present invention.

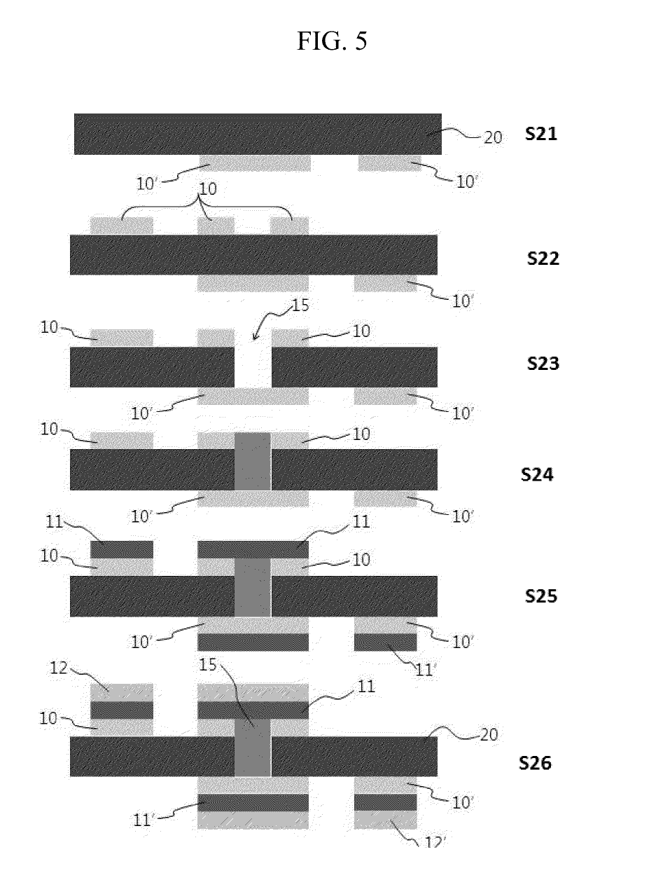

FIG. 3 is different from FIG. 2, in terms of the via being formed up to the patterned wiring layer made of the conductive paste. When the patterned wiring layer made of the conductive paste in the double-sided flexible printed circuit board includes the via land, the blind via hole formed by laser drilling may be plated or filled with the conductive material up to the wiring layer made of the conductive paste to form a via therein, which will be described later with reference to FIG. 5.

In addition, the present invention provides a method of manufacturing the double-sided flexible printed circuit board.

Depending on the sequence of formation of each wiring layer and via hole in the manufacturing process, various combinations may be provided. In the present invention, two types of methods for manufacturing a double-sided flexible printed circuit board are described herein.

According to one embodiment of the present invention, a method of manufacturing a double-sided flexible printed circuit board includes printing a conductive paste composition including any one selected from the following: a conductive Ag paste, a conductive Cu paste, a conductive polymer and a gravure paste or a mixture thereof in a predetermined pattern on one side of a flexible printed circuit board to form a patterned wiring layer which covers a portion for forming a via hole; forming a blind via hole as the via hole at a predetermined portion of the other side of the flexible printed circuit board including the patterned wiring layer, except for the patterned wiring layer covering the via hole of one side of the flexible printed circuit board; forming a via in the via hole to impart conductivity to the via hole; printing a conductive paste composition having any one selected from the following: a conductive Ag paste, a conductive Cu paste, a conductive polymer and a gravure paste or a mixture thereof in a predetermined pattern on the other side of the flexible printed circuit board to form a patterned wiring layer so that the wiring layer formed on the other side of the flexible printed circuit board is connected to the via formed in the via hole and thus electrically connected to the wiring layer formed on one side of the flexible printed circuit board; subjecting a transition metal to electroless plating on the patterned wiring layers respectively formed on both sides of the flexible printed circuit board to form electroless plating layers; and additionally forming metal electroplating layers or electroless metal plating layers on the electroless plating layers formed on both sides of the flexible printed circuit board, in order to increase the electrical conductivity of wirings including the patterned wiring layers and the electroless metal plating layers.

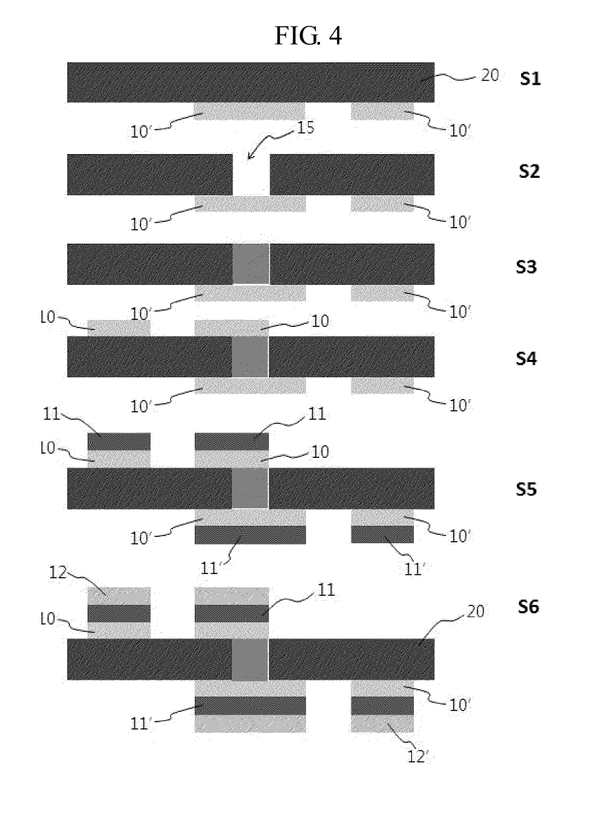

Referring to FIG. 4, a process of manufacturing the double-sided flexible printed circuit board according to an embodiment of the present invention may be described in more detail with the steps S1 through S6.

In the first step, the patterned wiring layer is formed of the conductive paste composition on one side of the flexible printed circuit board, provided that the wiring layer covers a portion for forming the via hole. The type and thickness of the flexible printed circuit board may remain the same as those described above.

The conductive paste composition may have a particle size in the range of 10 nm to 10 μm, and includes a conductive paste having nano-sized particles of 30 to 100 nm or a conductive paste having micro-sized particles of 1 to 7 μm.

The patterned wiring layer may be formed using pad printing, silk screen printing, or gravure printing, and then drying the paste may be further conducted depending on the processing conditions. As such, the drying process may be appropriately selected by those skilled in the art depending on the processing conditions, and thus the type thereof is without limitation, but hot air drying may be carried out at 80 to 200° C. or 100 to 160° C. for 10 min to 3 hr.

The paste may be subjected to a curing process depending on the conditions of use.

The conductive paste may be printed using a roll-to-roll process. The roll-to-roll process refers to a process of forming an electronic circuit by a printing process on a moving web (or a flexible substrate) using a system having an unwinder, a rewinder, an infeeder, an outfeeder, a printer, a drilling device and a controller for controlling longitudinal tension and lateral position between processes. This process is advantageous compared to other processes and systems because it allows for higher production rates and/or mass production.

In the present invention, covering the portion for forming the via hole with the wiring layer made of the conductive paste composition may be implemented by printing a conductive paste composition to form a via land in which the inside of the wiring is filled with the conductive paste composition. The portion printed with the conductive paste composition to form the via land corresponds to a portion which undergoes laser etching to form a blind via hole at the side opposite the side on which the via land wiring is formed in the subsequent procedures, and has to be sufficiently thick taking into consideration the damage due to laser etching or the etching potential. To this end, the thickness of the patterned wiring layer printed with the conductive paste composition should be at least 3 μm, 5 μm, or 7 μm or more.

In an exemplary embodiment, the patterned wiring layer may be manufactured by subjecting an Ag paste (a composition containing 62 wt % of a solvent and a curing agent) having an average particle diameter of 3˜5 μm to screen printing on a polyimide substrate 20 μm thick to form a wiring pattern, and then subjecting the substrate having the pattern to hot air drying at 150° C. for 30 min to 1 hr.

In the second step, forming the blind via hole at the predetermined portion of the other side of the flexible printed circuit board including the patterned wiring layer may be performed by etching the flexible circuit board using a drilling process. As such, a turn-over process may be adopted, which includes turning-over the substrate such that a drilling process is performed on the other side of the flexible printed circuit board.

As for the formation of the via hole in the present invention, the reason why the blind via hole, not the perforated via hole, is formed is to prevent pollution due to spilling of the conductive paste or conductive nano-ink in the subsequent procedures when the perforated via hole is used in the printing process of the conductive paste.

The via hole is used to interconnect printed circuits of the front and the rear side of the substrate, and drilling may generally include mechanical drilling or laser drilling. Particularly useful is laser drilling. In an exemplary embodiment, the via hole may be formed by etching the substrate using a UV or CO₂ laser. As such, the formation of the via hole as thick as the substrate at a specific position requires control of characteristics including laser output and motion control of a motor including controlling the position of a laser head.

After formation of the via hole, the method of the present invention may further include removing smear from the wall and the bottom of the via hole. Smear may be left behind inside the via hole due to heat caused by etching of the blind via hole using a laser, and may generate interfacial resistance of the via hole, undesirably creating reliability problems with the via hole. Hence, desmearing is performed using plasma treatment or chemical treatment. Plasma treatment includes vacuum plasma treatment using carbon tetrafluoride gas, and chemical treatment includes use of a material including permanganate.

In the third step, forming the via in the via hole to impart conductivity to the via hole may be performed by filling the via hole with a conductive material, a plating process, or a combination of a plating process and filling the via hole with a conductive material, as mentioned above.

In one embodiment, filling the via hole with the conductive material may be carried out by charging a conductive paste or a conductive ink including metal nanoparticles using inkjet printing.

For instance, when Ag is used as the metal for the conductive paste, a conductive nano-ink or a conductive paste comprising Ag powder and a thermosetting resin or a UV curable resin for binding the Ag powder is charged and then cured by heat or UV, thus forming the via.

On the other hand, the conductive ink comprising Ag nanoparticles may be discharged from the nozzle of an inkjet head to fill the via hole, and then heated, thus forming the via.

Because the via hole may be filled with metal nanoparticles having high electrical conductivity using the aforementioned process, without the need for electroplating, the manufacturing process is simplified, thus reducing manufacturing cost.

In the fourth step, printing the conductive paste composition in a predetermined pattern on the other side of the flexible printed circuit board to form the patterned wiring layer so that the wiring layer formed on the other side of the flexible printed circuit board is connected to the via formed in the via hole, and thus electrically connected to the wiring layer formed on one side of the flexible printed circuit board, may be carried out in the same manner as in the first step for forming the patterned wiring layer using the conductive paste. Because forming the patterned wiring layer on the other side of the flexible printed circuit board is executed after completion of laser etching, the wiring layer may be formed to be thinner, without the need to consider the damage due to laser etching or the etching potential.

The fourth step may be carried out using a roll-to-roll process as in the first step.

In the fifth step, subjecting the transition metal to electroless plating on the patterned wiring layers respectively formed on both sides of the substrate to form electroless plating layers, may be performed by forming an electroless plating layer on the paste using a transition metal salt, a reducing agent, and a complexing agent.

Electroless plating may be implemented by reducing the metal ion by means of a reducing agent in such a manner that a metal is reduced and deposited on the substrate using a plating solution including a metal ion-containing compound and a reducing agent.

The main reaction for reducing a metal ion is represented in the following Reaction 1.

Metal ion+2HCHO+4OH-=>Metal(0)+2HCOO⁻+H₂+2H₂O Reaction 1

Non-limited examples of the metal for use in electroless plating may include Ag, Cu, Au, Cr, Al, tungsten (W,) zinc (Zn), Ni, Fe, Pt, lead (Pb), Sn, and Au, which may be used alone or in combination of two or more.

The plating solution for electroless plating may include a salt of metal to be plated and a reducing agent, and non-limited examples of the reducing agent may include formaldehyde, hydrazine or salts thereof, cobalt (II) sulfate, formalin, glucose, glyoxylic acid, hydroxyalkylsulfonic acid or salts thereof, hypophosphorous acid or salts thereof, boron hydride, and dialkylamineborane. In addition thereto, a variety of reducing agents may be utilized depending on the type of metal.

Furthermore, the electroless plating solution may include a metal salt for producing a metal ion, a complexing agent for use as a ligand for the metal ion to thereby prevent the formation of an unstable solution due to reduction of the metal in a liquid phase, and a pH controller for maintaining the electroless plating solution at an appropriate pH so that the reducing agent is oxidized.

The thickness of the electroless metal plating layer may be 1 to 10 μm, and the metal for electroless metal plating may include any one selected from among Ag, Cu, Au, chromium (Cr), Al, W, Zn, Ni, Fe, Pt, Pb, Sn, Au, and alloys thereof.

For example, in order to form a Cu plating layer, an electroless plating layer may be formed to a thickness of 1 to 10 μm using an aqueous solution containing copper sulfate, formalin, sodium hydroxide, ethylenediaminetetraacetic acid (EDTA), and 2,2′-bipyridyl as an accelerator.

Electroless Cu plating may be performed using a Barrel plating device.

In one embodiment, electroless plating according to the present invention may be implemented through a plating process at 40˜80° C. and pH of 13 or more for 25 to 30 min after air stirring using a solution comprising 85% of D/I water, 10˜15% of a supplement, 2˜5% of 25% NaOH, 0.1˜1% of a stabilizer, and 0.5˜2% of 37% formalin for 10 to 15 min.

Also, the method of the present invention may further include forming a seed metal layer using any one selected from among Au, Ag, Pt, Cu, Ni, Fe, Pd, Co, and alloys thereof on the patterned wiring layer to form the electroless metal plating layer, between forming the patterned wiring layer using the conductive paste and forming the electroless plating layer using the transition metal on the patterned wiring layer. The seed metal layer may be made of a Pd salt.

In addition to the seed metal component, the other transition metal component may be further contained.

In the sixth step, additionally forming the metal plating layers on the electroless plating layers provided on both sides of the flexible printed circuit board may include forming metal plating layers using electroless plating or electroplating. Herein, forming the electroless plating layers may be carried out in the same manner as above.

As an example of the electroplating, Cu electroplating may be executed by immersing the substrate in an aqueous solution having copper sulfate (CuSO₄), sulfuric acid (H₂SO₄), and a brightener to form a Cu electroplating layer to a desired thickness, the surface of which is then washed with water, giving a desired Cu electroplating layer. Specifically, Cu electroplating may be implemented using an aqueous solution including 10 wt % sulfuric acid, 90 g/L copper sulfate, 2 ml/L Cu stabilizer, 5 ml/L Cu brightener, and 0.16 ml/L hydrochloric acid (HCl) at 40˜60° C.

Additionally, forming plating layers on the electroplating layers may be performed using electroless plating or electroplating as mentioned above.

For example, in order to form a new Ni plating layer on the Cu plating layer, the surface of electroplated Cu is electroplated with Ni using an aqueous solution including nickel sulfate, nickel chloride, and boric acid, then washed with water, sonicated with ionized water, and dewatered, thus manufacturing a product adapted for the required characteristics.

In the present invention, low resistance of the electroplating layer may result in high electrical conductivity. When lower resistance is required, the time taken to perform Cu electroplating is lengthened, so that the amount of metal to be plated may increase, thus decreasing the resistance.

In the method of manufacturing the double-sided flexible printed circuit board according to the present invention, at least one step may be performed using a roll-to-roll process. As such, a roll-to-roll process is applied to forming the patterned wiring layer using the conductive paste composition and forming the via hole and the via.

According to another embodiment of the present invention, a method of manufacturing a double-sided flexible printed circuit board includes printing a conductive paste composition including any one selected from the following: a conductive Ag paste, a conductive Cu paste, a conductive polymer and a gravure paste or a mixture thereof in a predetermined pattern on one side of a flexible printed circuit board to form a patterned wiring layer which covers a portion for forming a via hole; printing a conductive paste composition including any one selected from the following: a conductive Ag paste, a conductive Cu paste, a conductive polymer and a gravure paste or a mixture thereof in a predetermined pattern on the other side of the flexible printed circuit board to form a patterned wiring layer; forming a blind via hole as the via hole at a predetermined portion of the other side of the flexible printed circuit board including the patterned wiring layer, except for the patterned wiring layer covering the via hole of one side of the flexible printed circuit board; forming a via in the via hole to impart conductivity to the via hole so that the wiring layers respectively formed on both sides of the flexible printed circuit board are electrically connected to each other; subjecting a transition metal to electroless plating on the patterned wiring layers and the via formed on both sides of the flexible printed circuit board to form electroless plating layers; and additionally forming metal electroplating layers or electroless metal plating layers on the electroless plating layers provided on both sides of the flexible printed circuit board to increase the electrical conductivity of the wirings including the patterned wiring layers and the electroless metal plating layers.

When compared with the manufacturing method according to the aforementioned embodiment, the manufacturing method according to the present embodiment is the same in view of the construction including the patterned wiring layers made of the conductive paste, the via hole and the via, the electroless plating layers and the electroplating layers, but may differ in the sequence of formation of the via hole.

A detailed description thereof is given below with reference to FIG. 5. The cross-section of the second step of FIG. 5 shows the patterned wiring layers formed on both sides of the flexible printed circuit board, compared to FIG. 4.

As such, in the case of a specific side (e.g., the upper side in FIG. 5) of a flexible printed circuit board, the portion for forming the via hole does not undergo a printing process for forming a patterned wiring layer. Accordingly, when the via hole is formed using a laser, the formation of the wiring layer is obviated, thus shortening the working time.

As illustrated as S21 through S26 in FIG. 5, the cross-section of the third step shows the formed blind via hole, and the cross-section of the fourth step shows the formed via. Specifically, the method of manufacturing the double-sided flexible printed circuit board according to one embodiment is implemented in such a manner that the wiring layers are formed on both sides of the flexible printed circuit board, after which the blind via hole is formed and then plated or filled with the conductive material to form the via, thereby electrically connecting the wiring layers which are respectively formed on both sides of the flexible printed circuit board.

Forming the electroless plating layers and the electroplating layers as the subsequent procedures may remain the same as above.

The double-sided flexible printed circuit board according to the present invention may be manufactured more simply and eco-friendly compared to conventional double-sided flexible substrates using an etching process. Also, the metal plating layer that is formed on the conductive paste layer of the flexible printed circuit board is more uniform and the wiring may have increased electrical conductivity, compared to conventional techniques for forming the electroplating layer on the conductive paste layer.

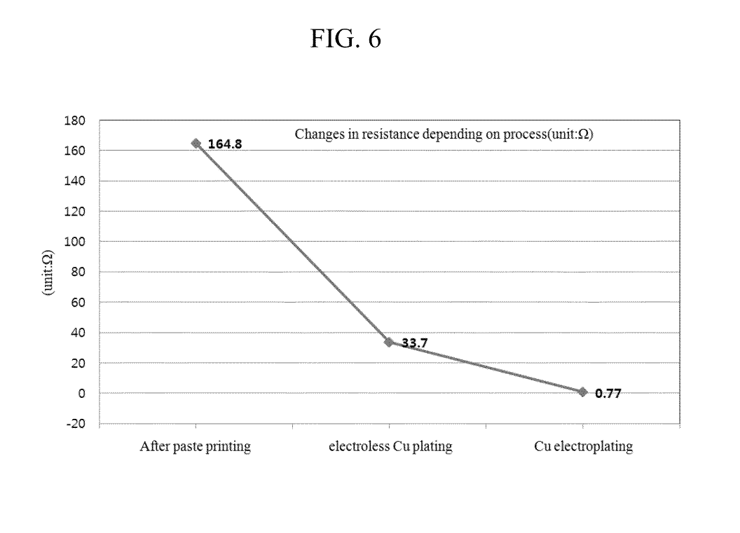

FIG. 6 illustrates measurement results for resistance at the start point and the finish point of the pattern when a wiring pattern with a width of 1 mm and a length of 750 mm is formed after 1) printing the conductive paste; 2) performing electroless Cu plating; and 3) performing Cu electroplating. The resistance was measured to be about 165Ω, which is regarded as comparatively high, in the presence of only the Ag paste layer. However, according to the present invention, the resistance was lowered to 34 Ω after electroless Cu plating and then to about 0.77 Ω after Cu electroplating, from which the conductivity is evaluated to be remarkably increased, resulting in significantly increased conductivity of the wiring.

Although the above-described embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A double-sided flexible printed circuit board, comprising
a flexible substrate including at least one via hole and a via formed therein to connect circuit wirings respectively formed on both sides of the substrate;
a patterned wiring layer formed by printing a conductive paste composition in a predetermined circuit wiring pattern on each of both sides of the flexible substrate;
an electroless metal plating layer formed on the patterned wiring layer; and
a metal plating layer additionally formed on the electroless metal plating layer to increase electrical conductivity of a wiring comprising the patterned wiring layer and the electroless metal plating layer formed on each of both sides of the flexible substrate,
wherein the circuit wirings respectively patterned on both sides of the flexible substrate are electrically connected to each other through the via formed in the via hole.

2. The double-sided flexible printed circuit board of claim 1, wherein the substrate has a thickness of 12 to 100 μm, and comprises any one selected from the group consisting of polybutylene terephthalate, polyethylene terephthalate, polysulfone, polyether, polyetherimide, heat-resistant epoxy, polyarylate, polyimide, and FR-4.

3. The double-sided flexible printed circuit board of claim 1, wherein the electroless metal plating layer formed on the patterned wiring layer has a thickness of 1 to 10 μm, and a metal for the electroless metal plating layer comprises any one selected from the group consisting of Cu, Sn, Ag, Au, Ni, and alloys thereof.

4. The double-sided flexible printed circuit board of claim 1, wherein the metal plating layer which is additionally formed on the electroless metal plating layer is a metal electroplating layer or an electroless metal plating layer, and a metal for the metal electroplating layer which is additionally formed comprises any one selected from the group consisting of Ni, Cu, Sn, Au, Ag, and alloys thereof, or a Ni—P alloy, and a metal for the electroless metal plating layer which is additionally formed comprises any one selected from the group consisting of Cu, Sn, Ag, Au, Ni, and alloys thereof.

5. The double-sided flexible printed circuit board of claim 1, wherein the conductive paste composition comprises any one selected from the group consisting of a conductive Ag paste, a conductive Cu paste, a conductive polymer, and a gravure paste, or a mixture thereof, and the conductive paste composition has a particle size of 10 nm to 10 μm.

6. The double-sided flexible printed circuit board of claim 1, wherein the via is formed in the via hole by filling the via hole with a conductive material, a plating process, or a combination of a plating process and filling the via hole with a conductive material.

7. The double-sided flexible printed circuit board of claim 6, wherein filling the via hole with the conductive material is performed by filling the via hole with a conductive paste or a conductive ink including metal nanoparticles using inkjet printing.

8. The double-sided flexible printed circuit board of claim 1, further comprising a seed metal layer formed of any one selected from the group consisting of Au, Ag, Pt, Cu, Ni, Fe, Pd, Co, and alloys thereof on the patterned wiring layer to form the electroless metal plating layer.

9. A method of manufacturing a double-sided flexible printed circuit board, comprising:
printing a conductive paste composition comprising any one selected from the group consisting of a conductive Ag paste, a conductive Cu paste, a conductive polymer, and a gravure paste, or a mixture thereof in a predetermined pattern on one side of a flexible printed circuit board, thus forming a patterned wiring layer which covers a portion for forming a via hole;
forming a blind via hole as the via hole at a predetermined portion of the other side of the flexible printed circuit board including the patterned wiring layer, except for the patterned wiring layer which covers the via hole of one side of the flexible printed circuit board;
forming a via in the via hole to impart conductivity to the via hole;
printing a conductive paste composition comprising any one selected from the group consisting of a conductive Ag paste, a conductive Cu paste, a conductive polymer, and a gravure paste, or a mixture thereof in a predetermined pattern on the other side of the flexible printed circuit board, thus forming a patterned wiring layer, so that the wiring layer formed on the other side of the flexible printed circuit board is connected to the via formed in the via hole and thus electrically connected to the wiring layer formed on one side of the flexible printed circuit board;
subjecting a transition metal to electroless plating on the patterned wiring layer provided on each of both sides of the flexible printed circuit board, thus forming an electroless plating layer; and
additionally forming a metal electroplating layer or an electroless metal plating layer on the electroless plating layer formed on each of both sides of the flexible printed circuit board in order to increase electrical conductivity of a wiring comprising the patterned wiring layer and the electroless metal plating layer.

10. The method of claim 9, wherein at least one step of the method is performed using a roll-to-roll process.

11. The method of claim 9, wherein forming the via hole is performed by etching using laser drilling.

12. The method of claim 9, further comprising removing smear from a wall and a bottom of the via hole, after forming the via hole.

13. The method of claim 9, wherein forming the via in the via hole to impart conductivity to the via hole is performed by filling the via hole with a conductive material, a plating process, or a combination of a plating process and filling the via hole with a conductive material.

14. The method of claim 9, further comprising forming a seed metal layer using any one selected from the group consisting of Au, Ag, Pt, Cu, Ni, Fe, Pd, Co and alloys thereof on the patterned wiring layer to form the electroless metal plating layer, between forming the patterned wiring layer using the conductive paste and forming the electroless plating layer using a transition metal on the patterned wiring layer.

15. A method of manufacturing a double-sided flexible printed circuit board, comprising:
printing a conductive paste composition comprising any one selected from the group consisting of a conductive Ag paste, a conductive Cu paste, a conductive polymer, and a gravure paste, or a mixture thereof in a predetermined pattern on one side of a flexible printed circuit board, thus forming a patterned wiring layer which covers a portion for forming a via hole;
printing a conductive paste composition comprising any one selected from the group consisting of a conductive Ag paste, a conductive Cu paste, a conductive polymer, and a gravure paste, or a mixture thereof in a predetermined pattern on the other side of the flexible printed circuit board, thus forming a patterned wiring layer;
forming a blind via hole as the via hole at a predetermined portion of the other side of the flexible printed circuit board including the patterned wiring layer, except for the patterned wiring layer which covers the via hole of one side of the flexible printed circuit board;
forming a via in the via hole to impart conductivity to the via hole so that the wiring layers respectively formed on both sides of the flexible printed circuit board are electrically connected to each other;
subjecting a transition metal to electroless plating on the patterned wiring layer and the via on each of both sides of the flexible printed circuit board, thus forming an electroless plating layer; and
additionally forming a metal electroplating layer or an electroless metal plating layer on the electroless plating layer provided on each of both sides of the flexible printed circuit board in order to increase electrical conductivity of a wiring comprising the patterned wiring layer and the electroless metal plating layer.

16. The method of claim 15, wherein at least one step of the method is performed using a roll-to-roll process.

17. The method of claim 15, wherein forming the via hole is performed by etching using laser drilling.

18. The method of claim 15, further comprising removing smear from a wall and a bottom of the via hole, after forming the via hole.

19. The method of claim 15, wherein forming the via in the via hole to impart conductivity to the via hole is performed by filling the via hole with a conductive material, a plating process, or a combination of a plating process and filling the via hole with a conductive material.

20. The method of claim 15, further comprising forming a seed metal layer using any one selected from the group consisting of Au, Ag, Pt, Cu, Ni, Fe, Pd, Co and alloys thereof on the patterned wiring layer to form the electroless metal plating layer, between forming the patterned wiring layer using the conductive paste and forming the electroless plating layer using a transition metal on the patterned wiring layer.
